(19) United States
(12) Patent Application Publication
(10) Pub. No.: US 2016/0124803 A1
(43) Pub. Date: May 5, 2016

(54) Storage Device Data Access Method and Storage Device

(71) Applicant: XI'AN SINOCHIP SEMICONDUCTORS CO., LTD., Xi-an Shaanxi (CN)

(72) Inventor: Alessandro MINZONI, Xi'an Shaanxi (CN)

(21) Appl. No.: 14/778,042

(22) PCT Filed: Mar. 19, 2014
(86) PCT No.: PCT/CN2014/073667

§ 371 Date: Jan. 25, 2016

(30) Foreign Application Priority Data
Mar. 19, 2013 (CN) 201310088811.7

(51) Int. Cl. G06F 11/10; H03M 13/19

(52) U.S. Cl. CPC G06F 11/1048; H03M 13/19; G06F 11/102

(57) ABSTRACT

Methods, devices, and systems for storage device data access and/or storage device error correction are provided. In one aspect, a storage device data access method comprises generating a parity bit for data to be stored; generating a flag bit that expresses whether a data mask is present or absent in the data to be stored; storing the data, the flag bit, and the parity bit; reading out the data, the flag bit and the parity bit; determining whether the data mask is present or absent based on the read out flag bit; in response to determining that the flag bit expresses the absence of the data mask, detecting and correcting the data using the read out parity bit; otherwise, in response to determining that the flag bit expresses the presence of the data mask, performing no detection or correction on the data.

### TECHNICAL FIELD

The present invention relates to a memory data access method and a memory.

### BACKGROUND ART

Error Correction Code (ECC) is used to detect and correct the incorrect data. It has been shown that numerous algorithms can support ECC, such as the common Hamming code, in which 8-bit data needs 4 parity bits and 64-bit data needs 7 parity bits. Thus, a proper algorithm may be selected according to the data length and the number of the data bits which need detection and correction.

For example, as to different Double Data Rate(DDR) structures (DDR1/2/3), the data prefetching length for typical stream in-and-out data reading is 32-bit, 64-bit, 128-bit, and the like. A reasonable and compromising solution is to use 7 parity bits or 8 parity bits for a 64-bit data (according to different ECC algorithms), as shown in FIGS. 1 and 2.

Nevertheless, as the presence of the Data Mask (DM), it is not easy for the DRAM to realize detection and correction functions. That is to say, when external data are written to a storage unit, since one or more Bytes may be masked off, the data previously stored in the storage unit will not be overwritten. In this way, the ECC encoding process will not generate parity bits successfully, as shown in FIG. 3. In order to solve this problem, the simplest method is to split 64-bit data into 8 groups and each group consists of 8-bit data (one Byte), precisely corresponding to the mask length of DM, so as not to be effected by DM. Nevertheless, since each 8-bit data needs 4 parity bits, the area of the whole storage array needs to increase by 50%, making the cost of DRAM be significantly increased. Therefore, it desperately needs a solution to address the problems brought out by DM.

### SUMMARY OF THE INVENTION

According to a first aspect of the invention, there is provided a memory error correction method, mainly for solving the problem that due to the presence of a data mask in the existing ECC encoding process, the encoding cannot smoothly proceed and thus the parity bits cannot be generated, or the area of the storage array needs to be increased even if the parity bits are generated.

The technical solutions of the present invention are as follows:

A memory error correction method, comprising the following steps:
1) writing external data, generating a parity bit and a flag bit simultaneously according to a given rule, and storing the external data, the flag bit and the parity bit to the memory, wherein the parity bit is used to achieve detection and error correction of data writing, and the flag bit is used to express whether a data mask is present or absent; if the data mask is present, invalidation of the parity bit is indicated, and if the data mask is absent, validation of the parity bit is indicated;
2) reading out the external data, the flag bit and the parity bit in the memory, wherein if the flag bit expresses the presence of the data mask, invalidation of the parity bit is indicated and decoding and error correction are not performed when data are read out, and if the flag bit expresses the absence of the data mask, validation of the parity bits is indicated and the parity bit is used to encode and correct error when data are read out.

According to a preferred embodiment of the first aspect of the present invention, when the above external data is 64-bit Hamming code, the parity bit is 7-bit, and the flag bit is 1-bit that is used as the 65th bit in a 65-bit data string.

According to a preferred embodiment of the first aspect of the present invention, if only 1-bit data is incorrect in the above step 2, no error correction is needed when the incorrect data is a flag bit or a parity bit; when the incorrect data is not a flag bit or a parity bit, whether a data mask is present or absent shall be judged based on the flag bit; if the data mask is absent, the parity bit is used to perform error correction on the external data, and if the data mask is present, error correction is not performed.

According to a preferred embodiment of the first aspect of the present invention, if two-bit or more data error is present in the above step 2, error correction is not performed.

According to a second aspect of the present invention, there is provided a memory data access method, characterized in that the method comprises the following steps:
generating a parity bit for data to be stored;
generating a flag bit, which expresses whether a data mask is present or absent in the data to be stored; and storing the data, the flag bit and the parity bit;
reading out the data, the flag bit and the parity bit;
wherein whether the data mask is present or absent shall be judged based on the flag bit; if the flag bit expresses the presence of the data mask, detection and correction are not performed on the data, and if the flag bit expresses the absence of the data mask, the parity bit is used to detect and correct the data.

According to a preferred embodiment of the second aspect of the present invention, the generated flag bit is stored as an independent part.

According to a preferred embodiment of the second aspect of the present invention, a parity bit for flag bit is generated for the generated flag bit, and the parity bit for flag bit and the flag bit together are stored.

According to a preferred embodiment of the second aspect of the present invention, after the flag bit and the parity bit for flag bit are read out, the parity bit for flag bit is used to detect and correct the flag bit.

According to a preferred embodiment of the second aspect of the present invention, the algorithm for generating a parity bit and the algorithm for generating a parity bit for flag bit are the same.

According to a preferred embodiment of the second aspect of the present invention, the flag bit is stored either as a data bit or as a parity bit.

According to a preferred embodiment of the second aspect of the present invention, if the flag bit expresses the absence of a data mask, the flag bit is removed from the data bit or from the parity bit prior to detection and correction on the data.

According to a third aspect of the invention, there is provided a memory, comprising:
a storage unit; a parity bit generation unit; a flag bit generation unit; a writing unit; a reading unit; and a correction unit;
wherein the parity bit generation unit generates for the data to be stored a parity bit, which is stored to the storage unit; the flag bit generation unit generates for the data to be stored a flag bit, which expresses whether a data mask is present or absent in the data to be stored and is stored to the storage unit; the writing unit writes the data to be stored to the storage unit; and
wherein the reading unit reads out the stored data, the flag bit and the parity bit from the storage unit; if the flag bit expresses the presence of the data mask, the correction unit performs no detection or correction on the read data, and if the flag bit expresses the absence of the data mask, the correction unit detects and corrects the read data.

According to a preferred embodiment of the third aspect of the present invention, the flag bit is stored in the storage unit as an independent part.

According to a preferred embodiment of the third aspect of the present invention, the flag bit generation unit generates a parity bit for flag bit for the flag bit, and the parity bit for flag bit and the flag bit together are stored in the storage unit.

According to a preferred embodiment of the third aspect of the present invention, a flag bit correction unit is further comprised, which uses the parity bit for flag bit to detect and correct the flag bit after the flag bit and the parity bit for flag bit are read out from the storage unit.

According to a preferred embodiment of the third aspect of the present invention, the algorithm for generating a parity bit and the algorithm for generating a parity bit for flag bit are the same.

According to a preferred embodiment of the third aspect of the present invention, the flag bit is stored in the storage unit either as a data bit or as a parity bit.

According to a preferred embodiment of the third aspect of the present invention, if the flag bit expresses the absence of a data mask, the correction unit removes the flag bit from the data bit or from the parity bit before detecting and correcting the data.

According to a preferred embodiment of the third aspect of the present invention, Hamming Code is used to generate a parity bit.

According to a preferred embodiment of the third aspect of the present invention, the memory is a dynamic random access memory.

The advantage of the present invention lies in that:

Whether a data mask is present or absent is judged by using a flag bit, and the memory data access method provided by the present invention can reduce the possibility of memory error when a data mask is present.

Furthermore, the present invention is suitable for various memory products in which a data mask is present, such as DRAM, SRAM, Flash, and the like.

### DESCRIPTION OF THE FIGURES

A better understanding of the present invention will be obtained with reference to the drawings. It should be understood that the drawings depict merely for an illustrative purpose and should not be deemed as limitations on the present invention.

FIG. 1 is a flow chart of an existing writing process of the ECC external data;

FIG. 2 is a flow chart of an existing reading process of the ECC external data;

FIG. 3 is a flow chart of an existing writing process of the ECC external data when there is a data mask;

FIG. 4 is a principle diagram of a method according to an embodiment of the present invention.

FIG. 5 is a schematic diagram of a memory according to an embodiment of the present invention.

### DETAILED DESCRIPTION

With reference to FIG. 1, the existing ECC encoding process can proceed in accordance with the following steps:

Firstly, the 64-bit external data are directly written (see A in FIG. 1).

Secondly, 7 parity bits or 8 parity bits (see B in FIG. 1, as an example, the 8 parity bits are shown in FIG. 1) are generated from the 64-bit external data by an ECC encoding circuit according to a given rule. The given rule is a specific ECC algorithm. That is to say, ECC encoding circuit generates parity bits according to the ECC algorithm practically employed. The parity bits are used to detect and correct the data.

Thirdly, the new 64-bit data and the 7 parity bits or 8 parity bits are written to the storage array and completely substitute for the previously information stored in the storage array (see C in FIG. 1).

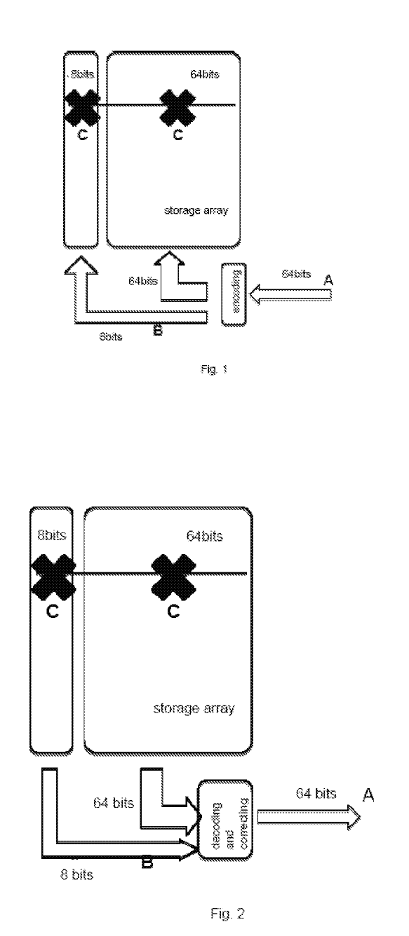

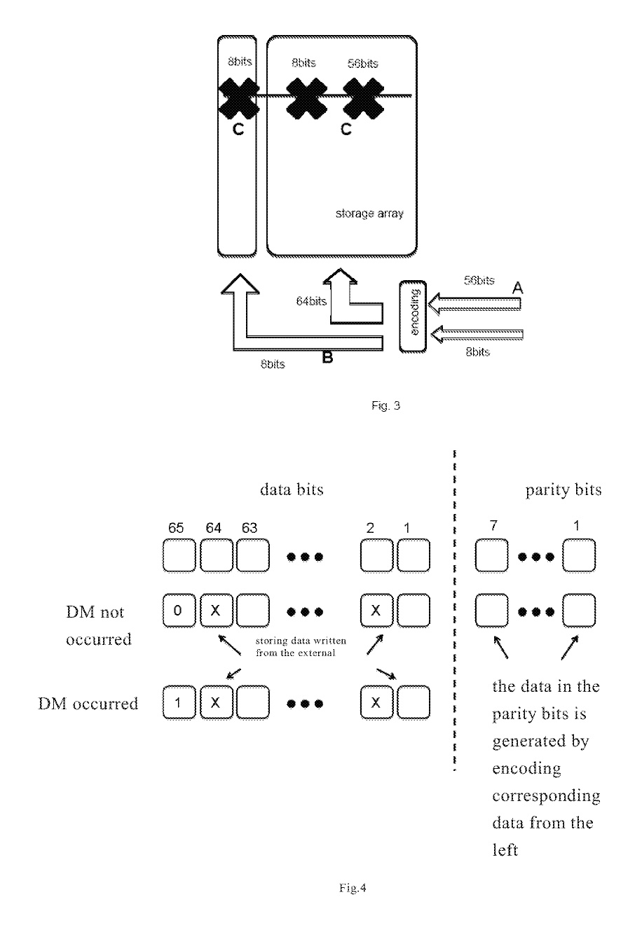

With reference to FIG. 2, the existing ECC decoding and correcting proceed in accordance with the following steps:

Firstly, the 64-bit data and 7 parity bits or 8 parity bits are read out from the storage array (see C in FIG. 2, as an example, the 8 parity bits are shown in FIG. 2).

Secondly, the parity bits will decode and judge whether there are errors in the data according to a give rule. If there is an error, the parity bits will judge which bit is error and correct the incorrect data (see B in FIG. 2). The rule used herein corresponds to the rule used during the encoding process in FIG. 1.

Thirdly, the decoded data is read out (see A in FIG. 2).

With reference to FIG. 3, when there is data mask, the existing ECC encoding will proceed in accordance with the following steps. Nevertheless, it should be understood that currently ECC encoding cannot work properly when there is data mask.

Firstly, the 56-bit data of the external 64-bit data are written to the storage array (see A in FIG. 3), and the remaining 8-bit data is masked off and is not written to the storage array.

Secondly, the parity bits are still generated from the external 64-bit data (see B in FIG. 3).

Thirdly, in the storage array, the 56-bit data of the 64-bit data are substituted by the external data written into the storage array, and the remaining 8-bit data still keep their original information. At this time, the parity bits are totally error parity bits for the 64-bit data (56-bit external data plus 8-bit original data) in the storage array (see C in FIG. 3).

Therefore, it desperately needs a method that can judge whether a data mask is present or absent when data is read out.

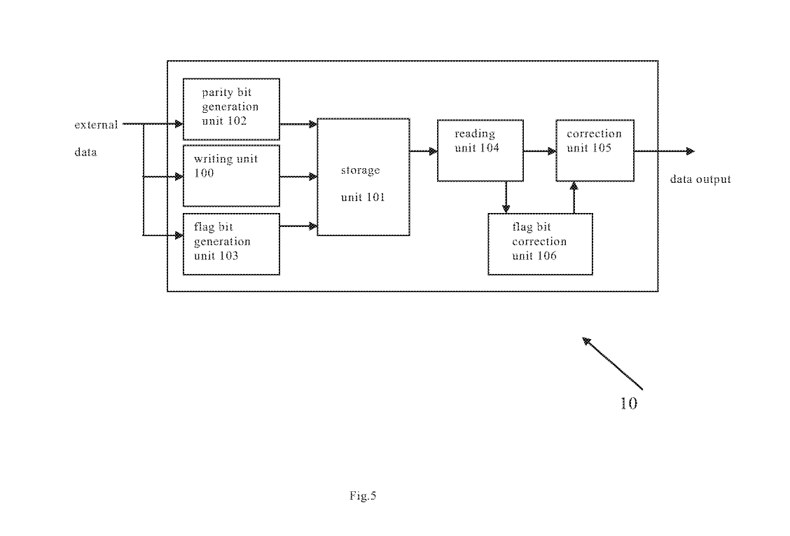

Hereinafter, the present invention will be described in detail with reference to FIG. 4 and the examples.

The concept of the method is to detect whether DM occurs, if DM occurs, invalidation of the parity bit is indicated and decoding and correction are not performed. The detection of whether DM occurs is performed based on the flag bit, which expresses whether a data mask is present or absent in the data.

Hamming code is taken as an example in the following examples. Nevertheless, it should be understood that for a storage, given the error rate and correction cost, the common ECC is a code that can detect two bits and correct one bit. Thus, as to the Hamming code in the embodiments of the present invention, the correction method of the present invention can correct one-bit error. Nevertheless, this does not mean the exclusion of other ECCs that can correct two-bit or more error, i.e., the present invention is also suitable for the situations where two-bit or more data are incorrect. That is to say, other algorithms, such as parity check, etc, can be used to generate parity bits.

For Hamming code, 64-bit data needs 7 parity bits to achieve the functions of detecting and correcting one-bit incorrect data. Thus, a flag bit can serve as one data bit in a 65-bit data string, and the flag bit will expresses whether DM occurs, as shown in FIG. 4. Nevertheless, it is should be understood that the flag bit can also serve as the 8th bit (every 8 bits in DRAM constitute a basic unit) in parity bits. The flag bit for this bit is free from encoding/decoding and correction of ECC. There is a need to judge whether decoding and correction are needed according to this data prior to decoding and correction. The judgment and decoding certainly can be performed at the same time to improve efficiency. For example, if “0” represents that there is no DM, and “1” represents that there is DM:
if the flag bit is “0”, decoding and correction are performed on the data; and
if the flag bit is “1”, decoding and correction are not performed on the data.

In the example of FIG. 4, bit width of the flag bit is 1. Nevertheless, it should be understood that bit width of the flag bit is not limited to 1 bit. It should also be understood that the data length in the present invention is also not limited to 64 bits shown in FIG. 4, and bit width of the parity bit depends on data length and the algorithm for generating the parity bit.

As described above, as a preferred embodiment according to the method of the present invention, the flag bit can be stored either as a data bit or as a parity bit. When the flag bit is stored either as a data bit or as a parity bit, if the flag bit expresses the absence of a data mask, the flag bit is removed from the data bit or from the parity bit prior to detection and correction on the data; if the flag bit expresses the presence of a data mask, when the flag bit is stored as a data bit, the flag bit is removed from the data bit but detection and correction are not performed on the data, and then the data is directly outputted, and when the flag bit is stored as a parity bit, no processing is performed on data and the data is directly outputted.

Furthermore, according to another preferred embodiment of the method of the present invention, the generated flag bit can be stored as an independent part, i.e., it can be stored as an individual part dependent of the data and the parity bit. When the flag bit is stored as an independent part, it is preferable to generate for the flag bit a parity bit for flag bit, which is used to detect and correct the flag bit, in order to improve reliability of the flag bit. The parity bit for flag bit and the flag bit together are stored. In this regard, after the flag bit and the parity bit for flag bit are read out, the parity bit for flag bit is used to detect and correct the flag bit, and subsequently whether a data mask is present or absent is judged based on the flag bit that has been detected and corrected.

Preferably, the algorithm for generating a parity bit and the algorithm for generating a parity bit for flag bit are the same.

FIG. 5 is a schematic diagram of a memory 10 according to an embodiment of the present invention. As shown in FIG. 5, the memory 10 comprises a writing unit 100, a storage unit 101, a parity bit generation unit 102, a flag bit generation unit 103, a reading unit 104 and a correction unit 105.

The parity bit generation unit 102 generates for the data to be stored a parity bit, which is stored to the storage unit 101 and used to detect and correct the data. The flag bit generation unit 103 generates for the data to be stored a flag bit, which expresses whether a data mask is present or absent in the data to be stored and is stored to the storage unit 101. The data is stored into the storage unit 101 via the writing unit 100.

The reading unit 104 reads out the stored data, flag bit and parity bit from the storage unit 101. If the flag bit expresses the presence of the data mask, the correction unit 105 performs no detection or correction on the read data, and the data is directly outputted from the memory 10; if the flag bit expresses the absence of the data mask, the correction unit 105 detects and corrects the read data, and then the detected and corrected data is outputted from the memory 10.

According to a preferred embodiment of the present invention, the flag bit can be stored as an independent part in the storage unit 101, i.e., it can be stored as an individual part dependent of the data and the parity bit. In this regard, preferably, the flag bit generation unit 103 can generate for the flag bit a parity bit for flag bit, which is used to detect and correct the flag bit. The parity bit for flag bit and the flag bit together are stored in the storage unit 101.

The memory 10 can further comprise a flag bit correction unit 106. After the reading unit 104 reads out the data, the parity bit, the flag bit, and the parity bit for flag bit from the storage unit 101, the flag bit and the parity bit for flag bit are sent to the flag bit correction unit 106, and the data and the parity bit are sent to the correction unit 105. The flag bit correction unit 106 uses the parity bit for flag bit to detect and correct the flag bit, and then the flag bit correction unit 106 sends the detected and corrected flag bit to the correction unit 105 for determining whether a data mask is present or absent based on the flag bit.

Preferably, the algorithm for generating a parity bit and the algorithm for generating a parity bit for flag bit are the same.

According to another preferred embodiment of the present invention, the flag unit can also be stored in the storage unit 101 either as a data bit or as a parity bit. At this time, after the reading unit 104 reads out the stored data, flag bit and parity bit from the storage unit 101, the data, the flag bit and the parity bit are sent to the correction unit 105. If the flag bit expresses the absence of a data mask, the correction unit 105 removes the flag bit from the data bit or from the parity bit prior to detection and correction on the data, then detection and correction are performed on the data, and the detected and corrected data are outputted from the memory. If the flag bit expresses the presence of a data mask, when the flag bit is stored as a data bit, the correction unit 105 removes the flag bits from the data bit but performs no detection and correction on the data, and then the data is directly outputted from the memory 10; when the flag bit is stored as a parity bit, the correction unit 105 performs no processing on the data, and the data is directly outputted from the memory 10.

According to an embodiment of the present invention, Hamming Code is used to generate a parity bit for the data to be stored.

According to an embodiment of the present invention, the memory is a dynamic random access memory.

While the above illustrate some embodiments of the present invention, it should be realized that the embodiments of the present invention are not limited to these above. Various modifications to the present invention can be made without departing from the scope of the invention.

1-21. (canceled)

22. A memory data access method comprising:
generating a parity bit for data to be stored;
generating a flag bit that expresses whether a data mask is present or absent in the data to be stored;
storing the data, the flag bit, and the parity bit;
reading out the data, the flag bit and the parity bit;
determining whether the data mask is present or absent based on the read out flag bit;
in response to determining that the flag bit expresses the absence of the data mask, detecting and correcting the data using the read out parity bit;
otherwise, in response to determining that the flag bit expresses the presence of the data mask, performing no detection or correction on the data.

23. The method of claim 22, wherein the generated flag bit is stored as an independent part.

24. The method of claim 23, further comprising:
generating a second parity bit for the generated flag bit; and
storing the second parity bit together with the generated flag bit.

25. The method of claim 24, further comprising:
after the flag bit and the second parity bit are read out, detecting and correcting the flag bit using the second parity bit.

26. The method of claim 24, wherein an algorithm for generating the parity bit for the data is same as an algorithm for generating the second parity bit for the flag bit.

27. The method of claim 22, wherein the flag bit is stored as one of a particular data bit and a particular parity bit.

28. The method of claim 27, further comprising:
in response to determining that the flag bit expresses the absence of the data mask, removing the flag bit from the one of the particular data bit and the particular parity bit prior to detection and correction on the data.

29. The method of claim 22, wherein generating the parity bit comprises generating the parity code using Hamming Code.

30. A system comprising:
a storage unit;
a parity bit generation unit;
a flag bit generation unit;
a writing unit;
a reading unit; and
a correction unit,
wherein the parity bit generation unit is configured to generate a parity bit for data to be stored, the flag bit generation unit is configured to generate for the data a flag bit that expresses whether a data mask is present or absent in the data, the writing unit is configured to write the data to the storage unit, and the storage unit is configured to store the data, the flag bit, and the parity bit, and
wherein the reading unit is configured to read out the stored data, the flag bit, and the parity bit from the storage unit, and
wherein the correction unit is configured to:
detect and correct the read out data in response to a determination of the flag bit expressing the absence of the data mask, and
perform no detection or correction on the read out data in response to a determination of the flag bit expressing the presence of the data mask.

31. The system of claim 30, wherein the flag bit is stored in the storage unit as an independent part.

32. The system of claim 31, wherein the flag bit generation unit is configured to generate a second parity bit for the flag bit, and the second parity bit and the flag bit together are stored in the storage unit.

33. The system of claim 32, further comprising a flag bit correction unit configured to use the second parity bit to detect and correct the flag bit after the flag bit and the second parity bit are read out from the storage unit.

34. The system of claim 32, wherein an algorithm for generating the parity bit for the data is same as an algorithm for generating the second parity bit for the flag bit.

35. The system of claim 30, wherein the flag bit is stored in the storage unit as one of a particular data bit and a particular parity bit.

36. The system of claim 35, wherein the correction unit is configured to:
in response to a determination of the flag bit expressing the absence of the data mask, remove the flag bit from the one of the particular data bit and the particular parity bit before detecting and correcting the data.

37. The system of claim 30, wherein the parity bit generation unit is configured to generate the parity bit using Hamming Code.

38. The system of claim 30, configured to be a dynamic random access memory.

39. A memory error correction method comprising:
writing external data;
generating a parity bit and a flag bit simultaneously according to a given rule, wherein the parity bit is used to achieve detection and error correction of data reading and the flag bit is used to express whether a data mask is present or absent;
storing the external data, the flag bit and the parity bit to a memory;
reading out the external data, the flag bit and the parity bit in the memory;
determining whether the data mask is present or absent using the flag bit;
in response to determining that the flag bit expresses the absence of the data mask, indicating validation of the parity bit and encoding and error correcting the data using the parity bit when the data are read out;
otherwise, in response to determining that the flag bit expresses the presence of the data mask, indicating invalidation of the parity bit and performing no decoding or error correction when the data are read out;

40. The memory error correction method of claim 39, wherein, when the external data is 64-bit Hamming code, the parity bit is generated to be 7-bit and the flag bit is generated to be 1-bit and as the 65th bit in a 65-bit data string.

41. The memory error correction method of claim 39, further comprising determining that only 1-bit data is incorrect when the data are read out, and in response:
if the incorrect data is the flag bit or the parity bit, performing no error correction, and
if the incorrect data is not the flag bit or the parity bit, determining whether the data mask is present or absent based on the flag bit, and performing error correction on the external data using the parity bit in response to determining that the data mask is absent, otherwise performing no error detection in response to determining that the data mask is present.

42. The memory error correction method of claim 41, further comprising:
in response to determining that two-bit or more data error is present when the data are read out, performing no error correction.
